(19) United States
(12) Patent Application Publication
(10) Pub. No.: US 2026/0304648 A1
(43) Pub. Date: Oct. 1, 2026

(54) DISPLAY DEVICE AND HOUSING THEREOF

(71) Applicant: Wistron Corporation, New Taipei City (TW)

(72) Inventors: HAOLIN DENG, New Taipei City (TW); GUOWEI HUANG, New Taipei City (TW); YOUGANG WANG, New Taipei City (TW); XIAOBO ZHANG, New Taipei City (TW)

(21) Appl. No.: 19/256,407

(22) Filed: Jul. 1, 2025

(30) Foreign Application Priority Data
Mar. 27, 2025 (CN) 202510377668.6

(51) Int. Cl. H05K 5/02

(52) U.S. Cl. CPC H05K 5/0217

(57) ABSTRACT

A housing of a display device is provided. The display device includes a panel assembly and a rear housing. The panel assembly includes a panel, limiting assembly portions, and first fixing assembly portions. The rear housing includes a rear plate, a rear housing middle frame, a front trim plate, limiting portions, and first fixing portions. The rear housing middle frame extends from the rear plate and includes a top frame plate, a first side frame plate, a second side frame plate, and a bottom frame plate. The front trim plate extends from the bottom frame plate. The limiting portions are located on the rear plate. The limiting portions are respectively connected to the limiting assembly portions, the first fixing portions are respectively connected to the first fixing assembly portions, and the panel assembly to be located between the rear plate and the front trim plate.

### CROSS-REFERENCE TO RELATED APPLICATION

This non-provisional application claims priority under 35 U.S.C. § 119(a) to Patent Application No. 202510377668.6 filed in China on Mar. 27, 2025, the entire contents of which are hereby incorporated by reference.

### BACKGROUND

### Technical Field

The present disclosure is related to a display device and a housing thereof, in particular to a display device including a rear housing having a rear plate, a rear housing middle frame, and a front trim plate at the same time.

### Related Art

Currently, in an assembly process of a display device on the market, a system middle frame needs to be first fixed to a panel assembly, a rear housing and the system middle frame then need to be fixed to each other, and then a front trim strip and the rear housing need to be fixed to each other, to complete assembly of the display device. The assembly process is not only complex but also time-consuming. Therefore, the assembly cost is high.

### SUMMARY

Based on the above, some embodiments of the present invention provide a display device including a rear housing having a rear plate, a rear housing middle frame, and a front trim plate at the same time. In an assembly process, the assembly is completed as soon as the panel assembly and the rear housing are fixed to each other. Such assembly process is simple and convenient, and reduces assembly time and costs. A one-piece structure of the rear housing further saves the material cost. Similarly, a disassembly process of the display device is also simple and convenient.

In some embodiments, a display device includes a panel assembly and a rear housing. The panel assembly includes a plurality of limiting assembly portions and a plurality of first fixing assembly portions. The rear housing includes a rear plate, a rear housing middle frame, a front trim plate, a plurality of limiting portions, and a plurality of first fixing portions. The rear housing middle frame extends from the rear plate and includes a top frame plate, a first side frame plate, a second side frame plate, and a bottom frame plate. The front trim plate extends from the bottom frame plate. The plurality of limiting portions are located on the rear plate. The plurality of limiting portions are respectively connected to the plurality of limiting assembly portions, and the plurality of first fixing portions are respectively connected to the plurality of first fixing assembly portions, to enable the panel assembly to be located between the rear plate and the front trim plate.

In some embodiments, the rear housing is a one-piece structure. The limiting portions are respectively matched with the limiting assembly portions, and the first fixing portions are respectively fixed to the first fixing assembly portions, so that the rear plate and the front trim plate are respectively located on two opposite sides of the panel assembly.

In some embodiments, the plurality of first fixing portions are located on the top frame plate, the first side frame plate, and the second side frame plate, so that the rear housing and the panel assembly are fixed to each other.

In some embodiments, the plurality of first fixing portions are located on the rear plate, so that the rear housing and the panel assembly are fixed to each other.

In some embodiments, the first fixing assembly portions and the limiting assembly portions are arranged in an alternating manner.

In some embodiments, the first fixing portions protrude toward the panel assembly, a side of a free end of each of the first fixing portions has a hook portion, and each of the first fixing portions is hooked to a corresponding one of the first fixing assembly portions through the hook portion.

In some embodiments, each of the first fixing assembly portions has a fixing assembly slot, the fixing assembly slot has a second opening, the second opening is provided at a bottom of the fixing assembly slot, and a corresponding one of the first fixing portions is hooked to the fixing assembly slot through the hook portion.

In some embodiments, the fixing assembly slot further has an inverted portion, and the inverted portion is arranged on a side of the second opening and corresponds to the hook portion.

In some embodiments, each of the limiting assembly portions has a first opening, and a corresponding one of the limiting portions is limited by the first opening.

In some embodiments, each of the limiting portions has a limiting slot, the limiting slot is located on a side of each of the limiting portions facing a corresponding one of the limiting assembly portions, two sides of the limiting slot respectively have a support sub-portion and a limiting sub-portion that protrude toward the corresponding one of the limiting assembly portions, a distance between the support sub-portion and the rear housing middle frame is less than a distance between the limiting sub-portion and the rear housing middle frame, and the limiting sub-portion is limited by the first opening.

In some embodiments, a width of the first opening is greater than a width of the limiting sub-portion.

In some embodiments, a side of the first opening has an ear portion, and the ear portion protrudes away from the rear housing.

In some embodiments, one side of the limiting sub-portion has a first guide inclined side and an abutting side, one end of the first guide inclined side is connected to the abutting side, and the abutting side pushes against the ear portion.

In some embodiments, another side of the limiting sub-portion has a second guide inclined side, and a spacing is provided between the second guide inclined side and the side of the first opening.

In some embodiments, a first gap is provided between the support sub-portion and the rear housing middle frame, and the panel assembly is partially arranged in the first gap.

In some embodiments, the rear housing further includes a plurality of supporting portions supporting the panel assembly.

In some embodiments, a second gap is provided between the supporting portion and the rear housing middle frame, and the panel assembly is partially arranged in the second gap.

In some embodiments, the panel assembly further includes an assembly middle frame and a middle rear frame, the assembly middle frame includes a plurality of second fixing assembly portions, the middle rear frame includes a plurality of second fixing portions, and the second fixing portions are fixed to the second fixing assembly portions.

According to some embodiments, a housing of a display device includes an assembly middle frame, a middle rear frame, and a rear housing. The assembly middle frame is fixed to the middle rear frame. The assembly middle frame includes a plurality of first fixing assembly portions. The middle rear frame includes a plurality of limiting assembly portions. The rear housing includes a rear plate, a rear housing middle frame, a front trim plate, a plurality of limiting portions, and a plurality of first fixing portions. The rear housing middle frame extends from the rear plate and includes a top frame plate, a first side frame plate, a second side frame plate, and a bottom frame plate. The front trim plate extends from the bottom frame plate, the limiting portions are located on the rear plate, the limiting portions are respectively connected to the limiting assembly portions, and the first fixing portions are respectively connected to the first fixing assembly portions, so that the assembly middle frame and the middle rear frame are located between the rear plate and the front trim plate.

Based on the above, some embodiments of the present invention provide a display device. An assembly process of the display device is simple and convenient. Therefore, the assembly process of the display device not only reduces assembly time and costs but also reduces material costs. Similarly, a disassembly process of the display device is also simple and convenient.

The following provides detailed descriptions by using specific embodiments with reference to the accompanying drawings, so that the objectives, technical content, and features of the present disclosure and effects achieved by the present invention can be easily understood.

### BRIEF DESCRIPTION OF THE DRAWINGS

FIG. 1 is a schematic three-dimensional diagram of a display device according to some embodiments;

FIG. 2 is a schematic three-dimensional exploded view of a first perspective of a display device according to some embodiments;

FIG. 3 is a schematic three-dimensional exploded view of a second perspective of the display device in the embodiment of FIG. 2, where the second perspective is approximately opposite to the first perspective;

FIG. 4 is a schematic partial cross-sectional view of a display device marked at a position 4-4 in the embodiment of FIG. 2, where a panel assembly and a rear housing are in an assembled state;

FIG. 5 is a schematic cross-sectional view of a disassembled display device marked at a position 5-5 in the embodiment of FIG. 3;

FIG. 6 is a schematic three-dimensional exploded view of a third perspective of the display device in the embodiment of FIG. 2, where the third perspective is the same as the perspective of FIG. 1;

FIG. 7 is a schematic partial cross-sectional view of a display device marked at a position 7-7 in the embodiment of FIG. 2, where a panel assembly and a rear housing are in an assembled state;

FIG. 8 is a schematic partial enlarged three-dimensional view of a fourth perspective of a middle rear frame of a display device marked at a position 8 in the embodiment of FIG. 6;

FIG. 9 is a schematic partial enlarged three-dimensional view of a fifth perspective of the middle rear frame of the display device in the embodiment of FIG. 8, where the fifth perspective is approximately opposite to the fourth perspective;

FIG. 10 is a schematic partial enlarged three-dimensional view of a rear housing of a display device marked at a position 10 in the embodiment of FIG. 6;

FIG. 11 is a schematic partial cross-sectional view of an assembly middle frame, a middle rear frame, and a rear housing of a display device marked at a position 11-11 in the embodiment of FIG. 6, where the assembly middle frame, the middle rear frame, and the rear housing are in an assembled state;

FIG. 12 is a schematic partial cross-sectional view of an assembly middle frame, a middle rear frame, and a rear housing of a display device marked at a position 12-12 in the embodiment of FIG. 6, where the assembly middle frame, the middle rear frame, and the rear housing are in an assembled state;

FIG. 13 is a schematic partial cross-sectional view of an assembly middle frame, a middle rear frame, and a rear housing of a display device marked at a position 13-13 in the embodiment of FIG. 6, where the assembly middle frame, the middle rear frame, and the rear housing are in an assembled state;

FIG. 14 is a schematic partial cross-sectional view of an assembly middle frame, a middle rear frame, and a rear housing of a display device marked at a position 14-14 in the embodiment of FIG. 6, where the assembly middle frame, the middle rear frame, and the rear housing are in an assembled state;

FIG. 15 is a schematic three-dimensional exploded view of a display device according to some embodiments;

FIG. 16 is a schematic partial cross-sectional view of a display device marked at a position 16-16 in the embodiment of FIG. 15, where a panel assembly and a rear housing are in an assembled state;

FIG. 17 is a schematic partial enlarged three-dimensional view of a sixth perspective of a middle rear frame of a display device marked at a position 17 in the embodiment of FIG. 15;

FIG. 18 is a schematic partial enlarged three-dimensional view of a seventh perspective of the middle rear frame of the display device in the embodiment of FIG. 17, where the seventh perspective is approximately opposite to the sixth perspective;

FIG. 19 is a schematic partial enlarged three-dimensional view of a rear housing of a display device marked at a position 19 in the embodiment of FIG. 15;

FIG. 20 is a schematic partial cross-sectional view of a middle rear frame and a rear housing of a display device marked at a position 20-20 in the embodiment of FIG. 15, where the middle rear frame and the rear housing are in an assembled state; and

FIG. 21 is a schematic partial cross-sectional view of a middle rear frame and a rear housing of a display device marked at a position 21-21 in the embodiment of FIG. 15, where the middle rear frame and the rear housing are in an assembled state.

### DETAILED DESCRIPTION

The following describes embodiments of the present invention in detail with reference to the drawings as examples. In the descriptions of the specification, to help readers understand the present invention more completely, many specific details are provided. However, the present invention may still be implemented under the condition that some or all of the specific details are omitted. In the drawings, identical or similar assemblies are represented by identical or similar symbols. It should be noted that the drawings are merely used for illustration and do not represent actual sizes or quantities of elements. Some details may not be completely drawn to maintain the simplicity of the drawings.

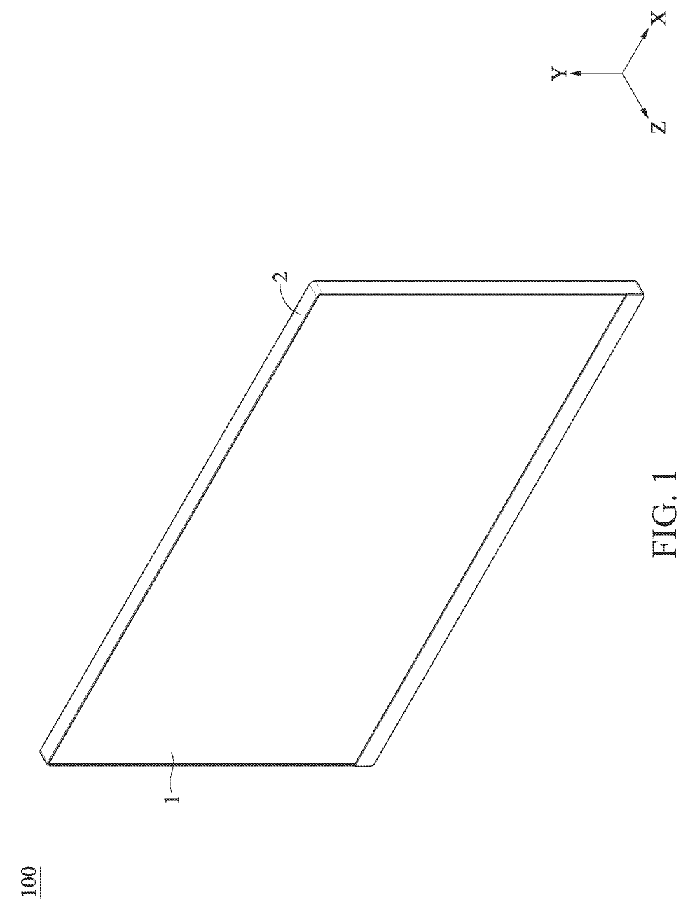

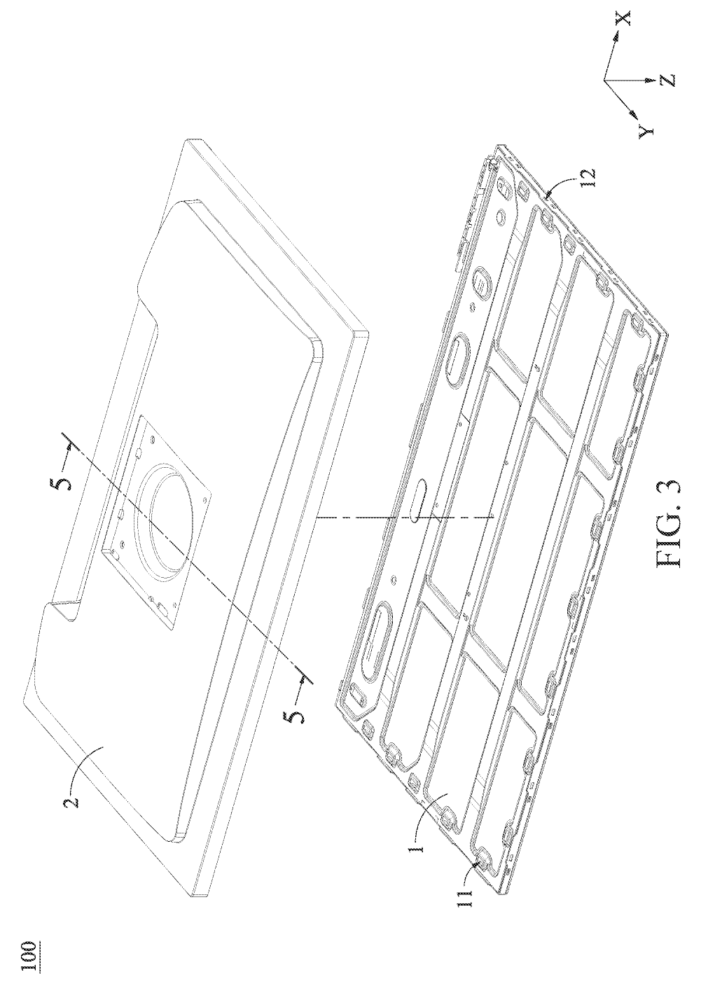

Referring to FIG. 1 to FIG. 3, a display device 100 includes a panel assembly 1 and a rear housing 2. The panel assembly 1 includes a plurality of limiting assembly portions 11 and a plurality of first fixing assembly portions 12. The rear housing 2 includes a rear plate 21, a rear housing middle frame 22, a front trim plate 23, a plurality of limiting portions 24, and a plurality of first fixing portions 25. The rear housing middle frame 22 extends from the rear plate 21. For example, in an embodiment, the rear housing middle frame 22 extends from an edge of the rear plate 21 and includes a top frame plate 22T, a first side frame plate 22S, a second side frame plate 22S', and a bottom frame plate 22B. The front trim plate 23 extends from the bottom frame plate 22B. The plurality of limiting portions 24 are located on the rear plate 21. The plurality of limiting portions 24 are respectively matched with the plurality of limiting assembly portions 11, and the plurality of first fixing portions 25 are respectively fixed to the plurality of first fixing assembly portions 12, so that the panel assembly 1 is located between the rear plate 21 and the front trim plate 23.

Based on the foregoing structure, an assembly process of the display device 100 is simple and convenient, and the assembly can be completed as soon as the panel assembly 1 and the rear housing 2 are fixed to each other, which not only reduces assembly time and costs but also reduces material costs. Similarly, a disassembly process of the display device 100 is also simple and convenient. In addition, through a specific ratio of a thickness of the panel assembly 1 to a height of the front trim plate 23, the display device 100 is assembled in a manner in which the panel assembly 1 is inserted into the rear housing 2 in an inclined direction and then the rear housing 2 and the panel assembly 1 are pressed and snapped together.

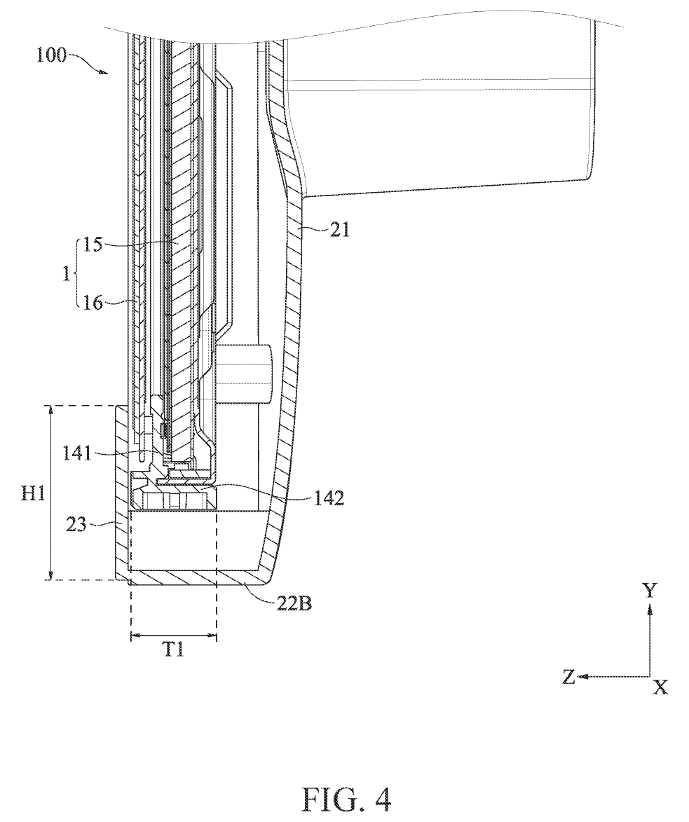

In some embodiments, the rear housing 2 is a one-piece structure. The plurality of limiting portions 24 are respectively matched with the plurality of limiting assembly portions 11, and the plurality of first fixing portions 25 are respectively fixed to the plurality of first fixing assembly portions 12, so that the rear plate 21 and the front trim plate 23 are respectively located on two opposite sides of the panel assembly 1. Referring to FIG. 4 together, the ratio of a thickness (referred to as a first thickness T1 below) of the panel assembly 1 to a height (referred to as a first height H1 below) of the front trim plate 23 is 35% to 70%. In some embodiments, the ratio of the first thickness T1 to the first height H1 is 40% to 60% or is 45% to 50%.

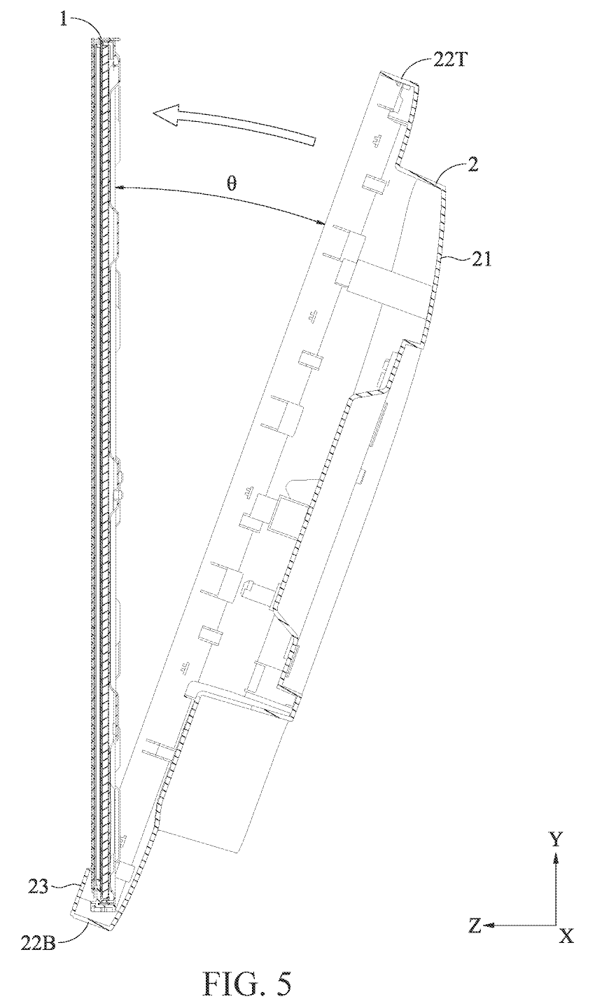

Referring to FIG. 5 together, in some embodiments, when an angle θ between the panel assembly 1 and the rear plate 21 is 30 degrees to 45 degrees, after a lower half of the panel assembly 1 is inserted into a space formed by the rear plate 21, the first side frame plate 22S, the second side frame plate 22S', the bottom frame plate 22B, and the front trim plate 23, an upper half of the panel assembly 1 is pressed into a space formed by the rear plate 21, the top frame plate 22T, the first side frame plate 22S, and the second side frame plate 22S', to complete assembly of the display device 100.

Still referring to FIG. 1 to FIG. 3, in some embodiments, the front trim plate 23 is connected to the bottom frame plate 22B, at least a part of the first side frame plate 22S, and at least a part of the second side frame plate 22S'.

Still referring to FIG. 1 to FIG. 3, in some embodiments, two sides of the top frame plate 22T are respectively connected to one side of the first side frame plate 22S and one side of the second side frame plate 22S', and the other side of the first side frame plate 22S and the other side of the second side frame plate 22S' are respectively connected to two sides of the bottom frame plate 22B.

Still referring to FIG. 1 to FIG. 3, in some embodiments, the rear plate 21, the rear housing middle frame 22, and the front trim plate 23 are all joined to the panel assembly 1.

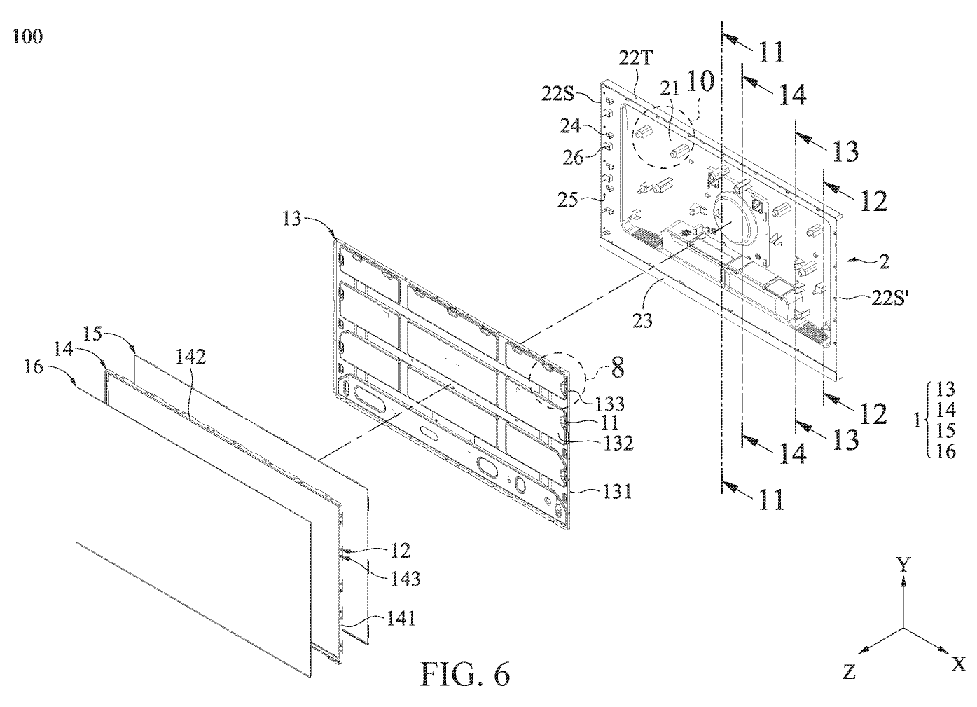

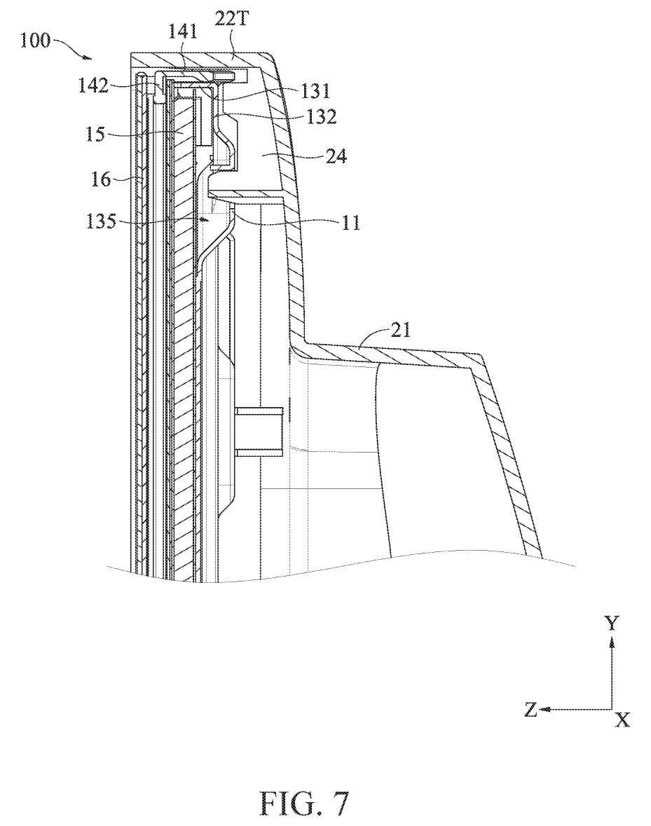

Referring to FIG. 6 to FIG. 10, in a first embodiment, the panel assembly 1 further includes a middle rear frame 13, a backlight module 15, an assembly middle frame 14, and a panel 16. The assembly middle frame 14 has a middle side frame plate 141 and a middle top frame plate 142, and the middle top frame plate 142 is connected to the middle side frame plate 141. The middle top frame plate 142 is joined to the panel 16. The backlight module 15 is joined to the middle top frame plate 142. The panel 16 and the backlight module 15 are joined to two opposite sides of the middle top frame plate 142. The middle rear frame 13 has a middle rear side frame plate 131 and a middle rear bottom frame plate 132. The middle rear bottom frame plate 132 is connected to the middle rear side frame plate 131 to form an accommodating space 135, the backlight module 15 is partially accommodated in the accommodating space 135 and is joined to the middle rear frame 13, and the middle rear side frame plate 131 is joined to the middle side frame plate 141. The rear plate 21 of the rear housing 2 is joined to the middle rear bottom frame plate 132, the rear housing middle frame 22 of the rear housing 2 is joined to the middle side frame plate 141, and the front trim plate 23 of the rear housing 2 is joined to at least a part of the panel 16 and at least a part of the middle top frame plate 142. The foregoing connection manners may independently be different connection manners, and each of the connection manners may include integral forming.

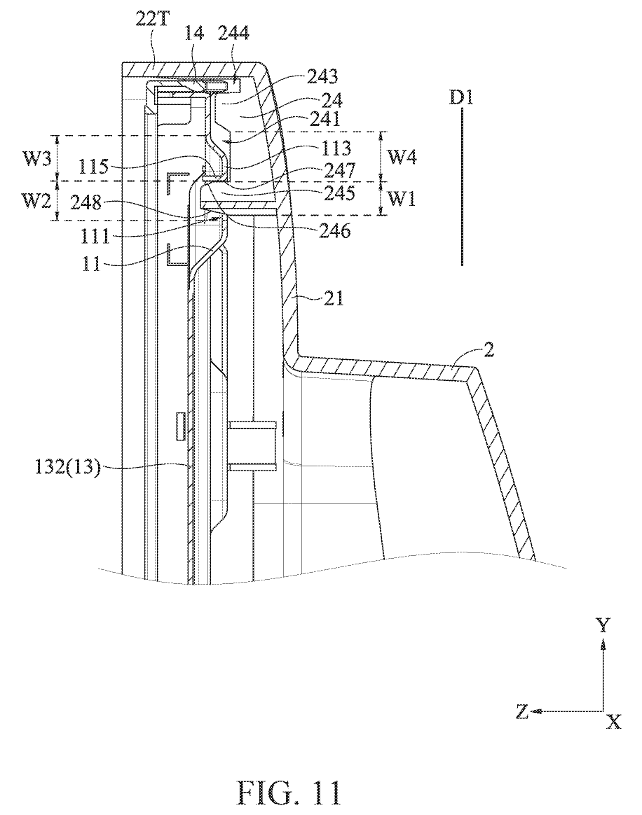

Referring to FIG. 11, in some embodiments, the limiting portion 24 is matched with the limiting assembly portion 11 to limit the rear housing 2. One end of the limiting portion 24 is located on the rear plate 21, and another end of the limiting portion 24 is located on the limiting assembly portion 11. The foregoing limiting refers to that a size margin (that is, allowance tolerance) is provided between elements assembled to each other in one or more directions, and an assembly relationship of the elements can be maintained within the margin range, but the assembly relationship between the assemblies can be removed in a direction other than a margin direction without an external force exceeding a specific threshold. Therefore, the foregoing limiting also covers a connection relationship of accommodation and possibility for two or more elements to be in contact with each other due to an external force. In this way, the limiting portion 24 of the rear housing 2 is limited by the limiting assembly portion 11 of the panel assembly 1, so that the rear housing 2 can be limited by the panel assembly 1, to prevent the rear housing 2 from shaking in one or more directions. In addition, through the configuration of the limiting portion 24 and the limiting assembly portion 11, the rear housing 2 can be quickly guided through the limiting assembly portion 11, and the rear housing 2 is assembled to the panel assembly 1, thereby reducing assembly time of elements. In some embodiments, the limiting assembly portion 11 is arranged on the middle rear bottom frame plate 132 of the middle rear frame 13. To keep the drawings from being messy, in FIG. 11, merely the middle rear frame 13 and the assembly middle frame 14 in the panel assembly 1 are drawn as an example, but the present invention is not limited thereto. In other words, the limiting assembly portion 11 may alternatively be arranged on the assembly middle frame 14, the backlight module 15, or the panel 16 in the panel assembly 1.

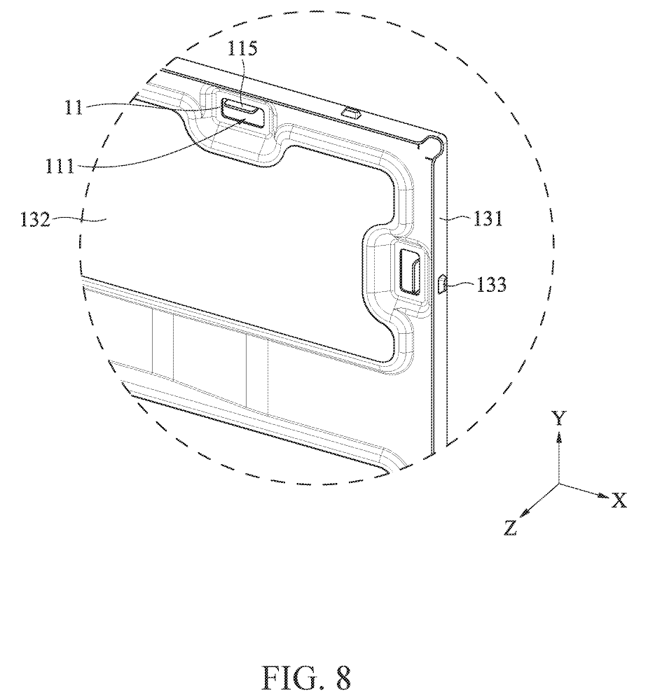

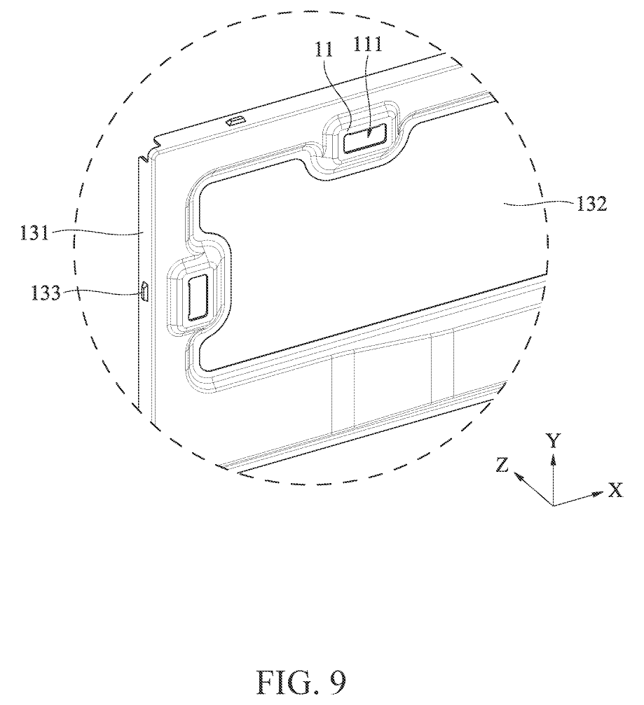

Referring to FIG. 8 and FIG. 9 together, in some embodiments, the limiting assembly portion 11 has a first opening 111, and the limiting portion 24 is limited by the first opening 111. In some embodiments, the panel assembly 1 has a limiting assembly portion 11 which protrudes and is similar to a hollow convex hull, and the limiting assembly portion 11 is located on a side of the panel assembly 1 facing the rear plate 21. The first opening 111 is located on a hollow part of the foregoing limiting assembly portion 11 which protrudes and is similar to the hollow convex hull. In this way, the limiting portion 24 is limited by the first opening 111, so that the rear housing 2 can be limited by the panel assembly 1, to prevent the rear housing 2 from shaking in one or more directions.

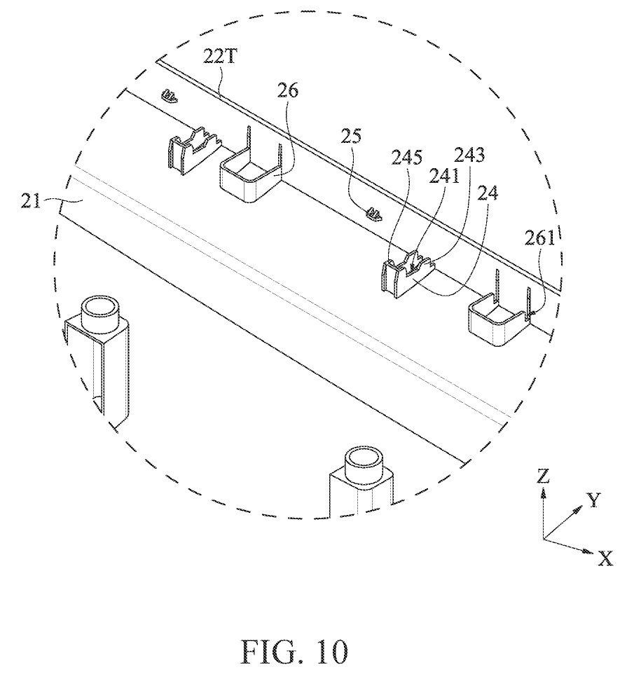

Referring to FIG. 10 together, in some embodiments, the limiting portion 24 has a limiting slot 241, and the limiting slot 241 is located on a side of the limiting portion 24 facing the limiting assembly portion 11. In other words, the limiting slot 241 is located on a side of the limiting portion 24 facing the panel assembly 1. Two sides of the limiting slot 241 respectively have a support sub-portion 243 and a limiting sub-portion 245 that protrude toward the limiting assembly portion 11. A distance between the support sub-portion 243 and the rear housing middle frame 22 (the top frame plate 22T in FIG. 11) is less than a distance between the limiting sub-portion 245 and the rear housing middle frame 22. In other words, in comparison with the limiting sub-portion 245, the support sub-portion 243 is closer to the rear housing middle frame 22.

Still referring to FIG. 11, in some embodiments, the limiting sub-portion 245 is limited by the first opening 111. A width of the first opening 111 is greater than a width of the limiting sub-portion 245. The limiting sub-portion 245 has a first width W1 in a first direction D1, the first opening 111 has a second width W2 in the first direction D1, and the second width W2 is greater than the first width W1, so that a first margin is provided between the first opening 111 and the limiting sub-portion 245 in the first direction D1. The first direction D1 is a direction parallel to the panel assembly 1 or the rear plate 21 of the rear housing 2. In this way, through the arrangement of the first opening 111, merely some of the limiting portion 24, the limiting sub-portion 245, may be accommodated in the limiting assembly portion 11, thereby limiting the limiting portion 24. Because the limiting sub-portion 245 can merely cause a displacement of the first margin at most in the first direction D1, the rear housing 2 and the limiting portion 24 thereof are limited in the first direction D1. In addition, the second width W2 is arranged to be greater than the first width W1, thereby facilitating assembly.

Still referring to FIG. 11, in some embodiments, the foregoing limiting assembly portion 11 which protrudes and is similar to the hollow convex hull has a protrusion portion 113, and the protrusion portion 113 is limited by the limiting slot 241. The protrusion portion 113 is located on a side of the panel assembly 1 facing the rear plate 21 and protrudes toward the limiting portion 24. The protrusion portion 113 protrudes toward the limiting slot 241. The protrusion portion 113 is located on the protrusion of the foregoing limiting assembly portion 11 which protrudes and is similar to the hollow convex hull. In this way, the protrusion portion 113 is limited by the limiting slot 241, so that the rear housing 2 can be limited by the panel assembly 1, to prevent the rear housing 2 from shaking in one or more directions. In addition, through the arrangement of the protrusion portion 113, the rear housing 2 can further be quickly guided through the protrusion portion 113, and the rear housing 2 is assembled to the panel assembly 1, thereby reducing assembly time of elements.

Still referring to FIG. 11, in some embodiments, a width of the limiting slot 241 is greater than a width of the protrusion portion 113. The protrusion portion 113 has a third width W3 in the first direction D1, the limiting slot 241 has a fourth width W4 in the first direction D1, and the fourth width W4 is greater than the third width W3, so that a second margin is provided between the limiting slot 241 and the protrusion portion 113 in the first direction D1. In this way, through the arrangement of the limiting slot 241, the protrusion portion 113 can be accommodated in the limiting slot 241, thereby limiting the limiting portion 24. Because the protrusion portion 113 can merely cause a displacement of the second margin at most in the first direction D1, the rear housing 2 and the limiting portion 24 thereof are limited in the first direction D1. In addition, the fourth width W4 is arranged to be greater than the third width W3, thereby facilitating assembly.

Referring to FIG. 8 together, in some embodiments, a side of the first opening 111 has an ear portion 115. The ear portion 115 protrudes toward the panel assembly 1, that is, protrudes away from the rear housing 2. In other words, the ear portion 115 protrudes toward the panel 16. The ear portion 115 has a smooth plane or a curved surface on one side of the first opening 111. The ear portion 115 may be formed by direct forming or subsequent processing. This is not limited herein and shall all both within the scope of the embodiments of the present invention.

Still referring to FIG. 11, in some embodiments, one side of the limiting sub-portion 245 has a first guide inclined side 246 and an abutting side 247, and one end of the first guide inclined side 246 is connected to the abutting side 247. The first guide inclined side 246 guides the limiting sub-portion 245 to enter the first opening 111, thereby achieving a limiting relationship between the rear housing 2 and the panel assembly 1. In addition, after the limiting sub-portion 245 enters the first opening 111, the abutting side 247 pushes against the ear portion 115, so that the abutting side 247 and the ear portion 115 push against each other, and thereby there is the limiting relationship between the rear housing 2 and the panel assembly 1. In some embodiments, the abutting side 247 is one side of the limiting slot 241. In some embodiments, another side (an opposite side of the side having the first guide inclined side 246 in the limiting sub-portion 245) of the limiting sub-portion 245 has a second guide inclined side 248. The second guide inclined side 248 also guides the limiting sub-portion 245 to enter the first opening 111, thereby achieving the limiting relationship between the rear housing 2 and the panel assembly 1. In some embodiments, a spacing is provided between the second guide inclined side 248 and one side of the first opening 111, and the spacing herein is the first margin provided between the first opening 111 and the limiting sub-portion 245 in the first direction D1. Because the limiting sub-portion 245 can merely cause a displacement of the first margin at most in the first direction D1, the rear housing 2 and the limiting portion 24 thereof are limited in the first direction D.

Still referring to FIG. 11, in some embodiments, a first gap 244 is provided between the support sub-portion 243 and the rear housing middle frame 22 (the top frame plate 22T in FIG. 11), and the panel assembly 1 is partially arranged in the first gap 244. In some embodiments, the assembly middle frame 14 of the panel assembly 1 is partially arranged in the first gap 244. In this way, through the arrangement of the first gap 244, the panel assembly 1 may be partially accommodated in the first gap 244, so that the rear housing 2 and the panel assembly 1 can be fixed to each other.

In some embodiments, the first fixing portion 25 is matched with the first fixing assembly portion 12, so that the rear housing 2 and the panel assembly 1 are fixed to each other. One end of the first fixing portion 25 is located on the rear housing 2, and another end of the first fixing portion 25 is located on the first fixing assembly portion 12. In some embodiments, the first fixing portion 25 of the rear housing 2 is hooked to the first fixing assembly portion 12 of the panel assembly 1. The first fixing assembly portion 12 may be a concave portion or a convex portion and is arranged in correspondence to the first fixing portion 25, so that the first fixing assembly portion 12 and the first fixing portion 25 are matched with and hooked to each other. The matching and hooking refers to that there is a physical fixing effect between elements hooked to each other, and the hooking relationship between the elements can be removed only through an external force greater than a specific threshold. Therefore, the matching and hooking also cover a hooking connection relationship in which the elements are detachable and can be repeatedly disassembled and assembled. In this way, the first fixing portion 25 and the first fixing assembly portion 12 are matched with and hooked to each other, so that the panel assembly 1 and the rear housing 2 can be fixed to each other. In some embodiments, the first fixing assembly portion 12 is arranged as a concave portion or an opening, and the first fixing portion 25 is arranged as a convex portion. In some other embodiments, the first fixing assembly portion 12 is arranged as a convex portion, and the first fixing portion 25 is arranged as a concave portion or an opening.

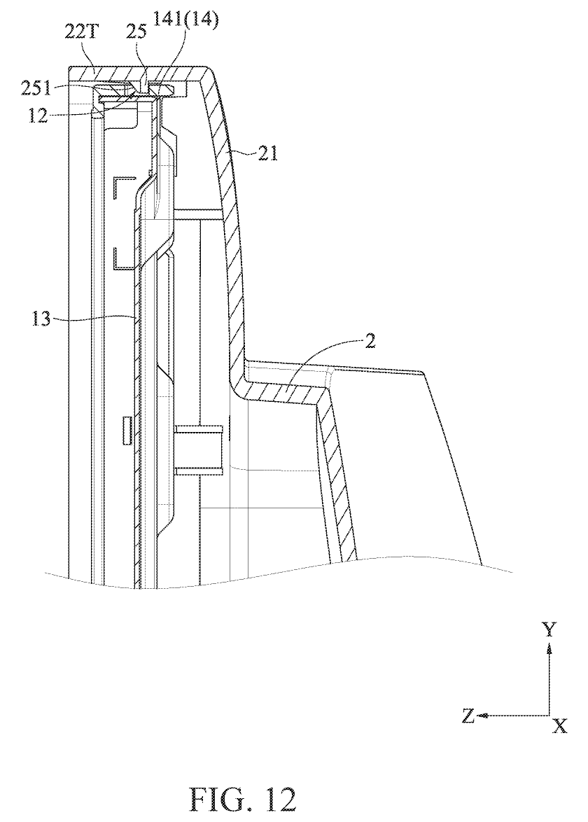

Referring to FIG. 12, in some embodiments, the first fixing assembly portion 12 is arranged on the middle side frame plate 141 of the assembly middle frame 14 and is arranged as an opening. To keep the drawings from being messy, in FIG. 12, merely the middle rear frame 13 and the assembly middle frame 14 in the panel assembly 1 are drawn as an example, but the present invention is not limited thereto. In other words, the first fixing assembly portion 12 may alternatively be arranged on another assembly in the panel assembly 1.

Referring to FIG. 6 together, in some embodiments, the plurality of first fixing portions 25 are located on the top frame plate 22T, the first side frame plate 22S, and the second side frame plate 22S', so that the rear housing 2 and the panel assembly 1 are fixed to each other. One end of the first fixing portion 25 is located on the top frame plate 22T, the first side frame plate 22S, or the second side frame plate 22S', and another end of the first fixing portion 25 is located on the first fixing assembly portion 12. The first fixing portion 25 is arranged as a convex portion, and the first fixing assembly portion 12 is arranged as a concave portion and corresponds to the first fixing portion 25. The first fixing assembly portion 12 and the first fixing portion 25 correspond to each other and are matched with and hooked to each other. In this way, the first fixing portion 25 of the rear housing 2 is hooked to the first fixing assembly portion 12 of the panel assembly 1, and the first fixing portion 25 and the first fixing assembly portion 12 are matched with and hooked to each other, so that the panel assembly 1 and the rear housing 2 can be fixed to each other.

Still referring to FIG. 12, in some embodiments, the first fixing portion 25 is arranged as a convex portion (while the first fixing assembly portion 12 is arranged as a concave portion corresponding to the convex portion), and the convex portion has a first guide inclined surface 251. A height of the first guide inclined surface 251 increases in a direction from a position far away from the rear housing middle frame 22 (the top frame plate 22T in FIG. 12) to a position close to the rear housing middle frame 22. In other words, the height of the first guide inclined surface 251 increases in a direction in which the first fixing assembly portion 12 is connected to the first fixing portion 25. For example, in an embodiment, such direction is a direction in which the first fixing assembly portion 12 is embedded in the first fixing portion 25. In other words, a side of the first guide inclined surface 251 away from the rear housing middle frame 22 has a shortest height, and the closer the first guide inclined surface 251 is to the rear housing middle frame 22, the higher the height of the first guide inclined surface 251 is, so that a side of the first guide inclined surface 251 close to the rear housing middle frame 22 has a highest height. In other words, an acute angle is provided between the first guide inclined surface 251 and the rear housing middle frame 22. In this way, through the arrangement of the first guide inclined surface 251 of the first fixing portion 25, when the first fixing portion 25 is hooked to the first fixing assembly portion 12, the convex portion can be quickly guided to the concave portion, and the convex portion can be effectively hooked to the concave portion, thereby reducing the assembly time of the elements.

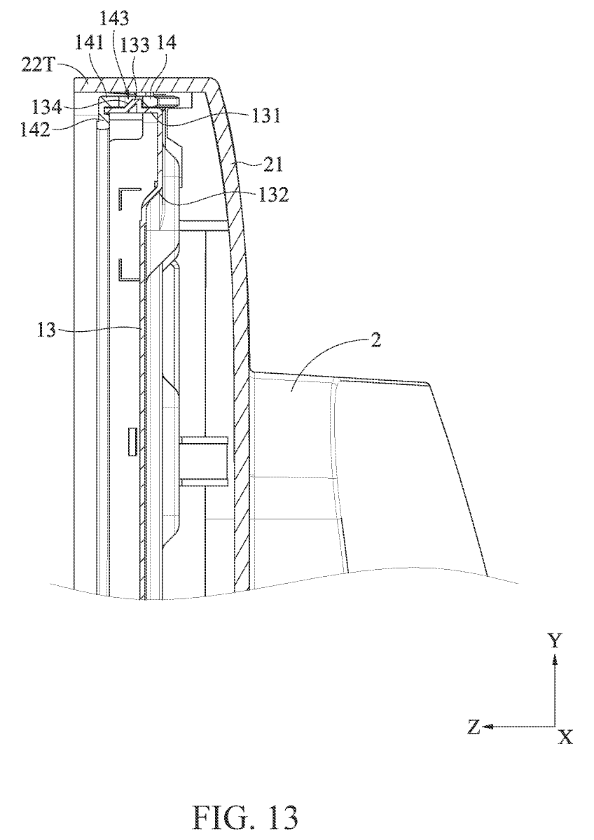

Referring to FIG. 6 and FIG. 13, in some embodiments, to enable the middle rear frame 13 and the assembly middle frame 14 to be fixed to each other, the assembly middle frame 14 further includes a plurality of second fixing assembly portions 143, and the middle rear frame 13 further includes a plurality of second fixing portions 133. The middle rear frame 13 and the assembly middle frame 14 are fixed to each other through matching between the second fixing portion 133 and the second fixing assembly portion 143. One end of the second fixing portion 133 is located on the middle rear frame 13, and another end of the second fixing portion 133 is located on the second fixing assembly portion 143. In some embodiments, the second fixing portion 133 of the middle rear frame 13 is hooked to the second fixing assembly portion 143 of the assembly middle frame 14. The second fixing assembly portion 143 may be a concave portion or a convex portion and is arranged in correspondence with the second fixing portion 133, so that the second fixing assembly portion 143 and the second fixing portion 133 are matched with and hooked to each other. The matching and hooking refers to that there is a physical fixing effect between elements hooked to each other, and the hooking relationship between the elements can be removed only through an external force greater than a specific threshold. Therefore, the matching and hooking also cover a hooking connection relationship in which the elements are detachable and can be repeatedly disassembled and assembled. In this way, the second fixing portion 133 and the second fixing assembly portion 143 are matched with and hooked to each other, so that the middle rear frame 13 and the assembly middle frame 14 can be fixed to each other. In some embodiments, the second fixing assembly portion 143 is arranged as a concave portion or an opening, and the second fixing portion 133 is arranged as a convex portion. In some other embodiments, the second fixing assembly portion 143 is arranged as a convex portion, and the second fixing portion 133 is arranged as a convex portion or an opening.

Still referring to FIG. 13, in some embodiments, the plurality of second fixing portions 133 are located on the middle rear side frame plate 131, so that the middle rear frame 13 and the assembly middle frame 14 are fixed to each other. One end of the second fixing portion 133 is located on the middle rear side frame plate 131, and another end of the second fixing portion 133 is located on the second fixing assembly portion 143. The second fixing portion 133 is arranged as a convex portion, and the second fixing assembly portion 143 is arranged on the middle side frame plate 141 of the assembly middle frame 14, is arranged as an opening, and corresponds to the second fixing portion 133. The second fixing assembly portion 143 and the second fixing portion 133 correspond to each other and are matched with and hooked to each other. In this way, the second fixing portion 133 of the middle rear frame 13 is hooked to the second fixing assembly portion 143 of the assembly middle frame 14, and the second fixing portion 133 and the second fixing assembly portion 143 are matched with and hooked to each other, so that the middle rear frame 13 and the assembly middle frame 14 can be fixed to each other.

Still referring to FIG. 13, in some embodiments, the second fixing portion 133 is arranged as a convex portion (while the second fixing assembly portion 143 is arranged as an opening corresponding to the convex portion), and the convex portion has a second guide inclined surface 134. A height of the second guide inclined surface 134 increases in a direction from a position far away from the middle rear side frame plate 131 to a position close to the rear housing middle frame 22. In other words, the height of the second guide inclined surface 134 increases in a direction in which the second fixing assembly portion 143 is connected to the second fixing portion 133. For example, in an embodiment, such direction is a direction in which the second fixing assembly portion 143 is embedded in the second fixing portion 133. In other words, a side of the second guide inclined surface 134 away from the middle rear side frame plate 131 has a shortest height, and the closer the second guide inclined surface 134 is to the middle rear side frame plate 131, the higher the height of the second guide inclined surface 134 is, so that a side of the second guide inclined surface 134 close to the middle rear side frame plate 131 has a highest height. In other words, an acute angle is provided between the second guide inclined surface 134 and the middle rear side frame plate 131. In this way, through the arrangement of the second guide inclined surface 134 of the second fixing portion 133, when the second fixing portion 133 is hooked to the second fixing assembly portion 143, the convex portion can be quickly guided to the opening, and the convex portion can be effectively hooked to the opening, thereby reducing the assembly time of the elements.

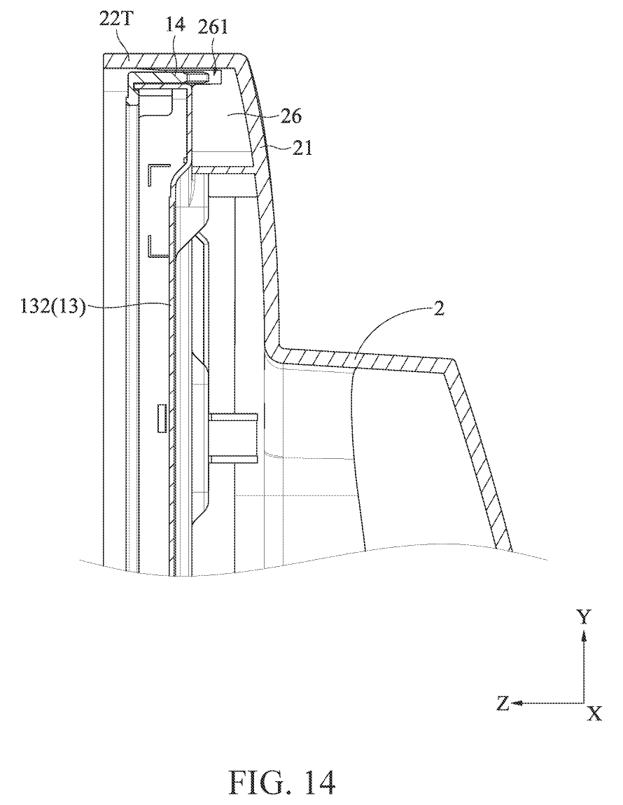

Referring to FIG. 6, FIG. 10, and FIG. 14, in some embodiments, the rear housing 2 further includes a plurality of supporting portions 26 supporting the panel assembly 1. In some embodiments, the supporting portions 26 are not arranged immediately next to each other, the limiting portions 24 are not arranged immediately next to each other, and the first fixing portions 25 are not arranged immediately next to each other. For example, at least one limiting portion 24 or one first fixing portion 25 is between any two supporting portions 26, at least one supporting portion 26 or one first fixing portion 25 is between any two limiting portions 24, and at least one supporting portion 26 or one limiting portion 24 is between any two first fixing portions 25. The supporting portions 26 and the limiting portions 24 are located on a side of the rear plate 21 close to the rear housing middle frame 22, and the first fixing portions 25 is located on the rear housing middle frame 22. An arrangement direction of the supporting portions 26 and an arrangement direction of the limiting portions 24 are the same as an axial direction of the adjacent rear housing middle frame 22. In some embodiments, the plurality of supporting portions 26 are located on the rear plate 21 to provide a supporting force for the panel assembly 1 from a rear side of the panel assembly 1. In some embodiments, at least a part of the supporting portions 26 and at least a part of the limiting portions 24 are connected to the adjacent rear housing middle frame 22. In some embodiments, the supporting portions 26 are located on the rear plate 21 and are adjacent to the middle rear frame 13. To keep the drawings from being messy, in FIG. 14, merely the middle rear frame 13 and the assembly middle frame 14 in the panel assembly 1 are drawn as an example, but the present invention is not limited thereto. In some embodiments, the supporting portions 26 are located on the rear plate 21 and are adjacent to the middle rear bottom frame plate 132 to provide the supporting force for the panel assembly 1.

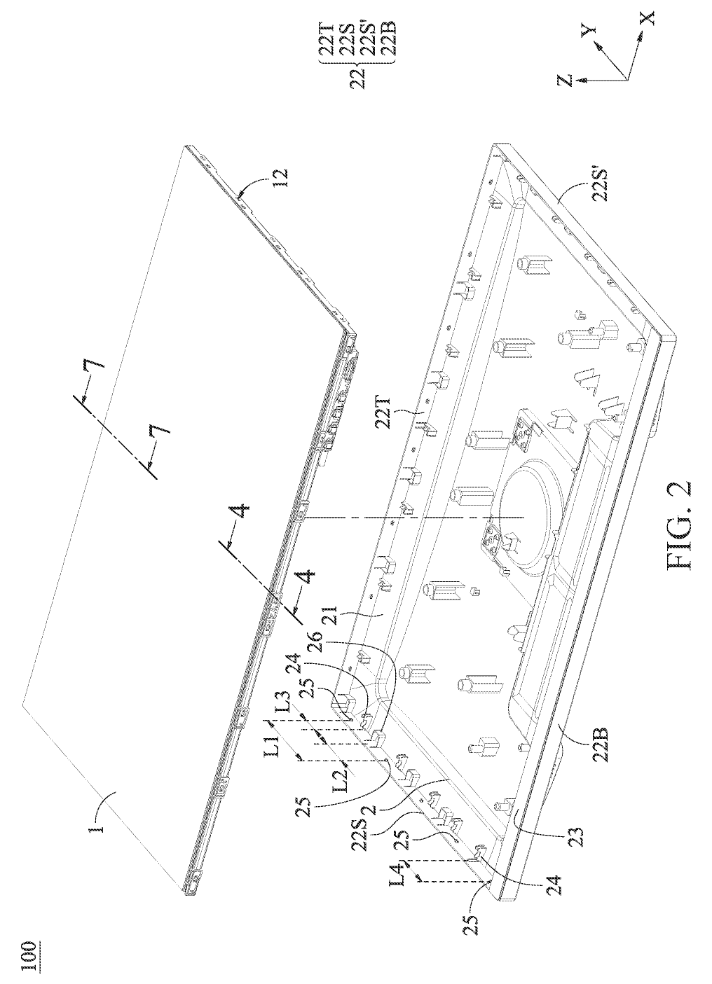

Referring to FIG. 2, a spacing between two adjacent ones of the first fixing portions 25 is L1, one of the limiting portions 24 and one of the supporting portions 26 are located between the two adjacent ones of the first fixing portions 25, a spacing between the supporting portion 26 and one of the two adjacent ones of the first fixing portions 25 which is adjacent to the supporting portion 26 (that is, a center distance between the supporting portion 26 and the first fixing portion 25, which is the same below, and this is not described in detail again) is L2, and a spacing between the limiting portion 24 and one of the two adjacent ones of the first fixing portions 25 which is adjacent to the limiting portion 24 is L3. In the embodiment of FIG. 2, L1 is 40 mm to 85 mm, L2 is 15 mm to 30 mm, and L3 is 5 mm to 25 mm. However, in a design in which there is merely the limiting portion 24 between two adjacent first fixing portions 25, a spacing between the limiting portion 24 and one of the two adjacent ones of the first fixing portions 25 which is adjacent to the limiting portion 24 is L4, and L4 is 20 mm to 45 mm, but this is not limited thereto, and L4 may alternatively be 5 mm to 45 mm. Under the condition of the foregoing spacing design, combined with size design and material selection of the first fixing portions 25, the limiting portion 24, and the supporting portion 26, assembly strength needed by a design can be obtained.

Referring to FIG. 10 and FIG. 14, in some embodiments, a second gap 261 is provided between the supporting portion 26 and the rear housing middle frame 22 (the top frame plate 22T in FIG. 10 and FIG. 14), and the panel assembly 1 is partially arranged in the second gap 261. In some embodiments, the assembly middle frame 14 of the panel assembly 1 is partially arranged in the second gap 261. In this way, through the arrangement of the second gap 261, the panel assembly 1 may be partially accommodated in the second gap 261, so that the rear housing 2 and the panel assembly 1 can be fixed to each other.

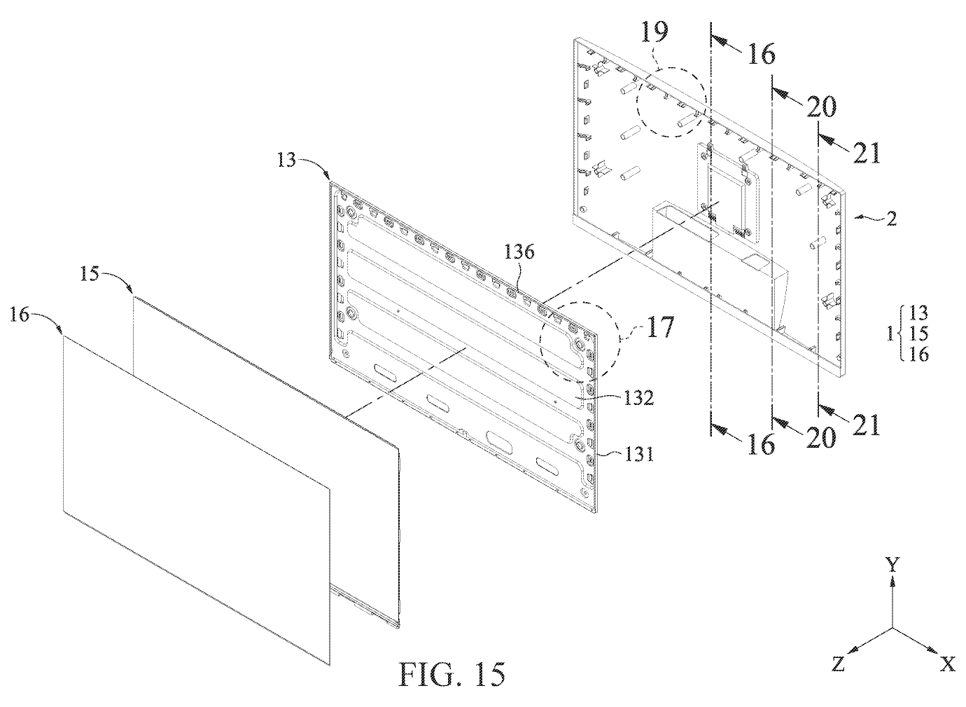

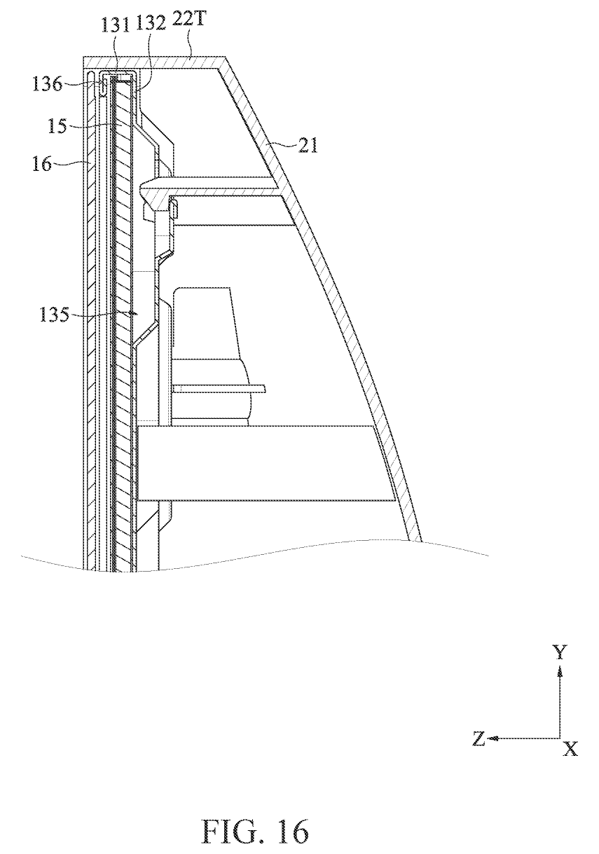

Referring to FIG. 15 to FIG. 19, in a second embodiment, the panel assembly 1 further includes the middle rear frame 13, the backlight module 15, and the panel 16. The middle rear frame 13 has the middle rear side frame plate 131, the middle rear bottom frame plate 132, and a middle rear top frame plate 136. The middle rear bottom frame plate 132 is connected to the middle rear side frame plate 131, and the middle rear side frame plate 131 is connected to the middle rear top frame plate 136. The panel 16 is joined to the middle rear top frame plate 136. The middle rear top frame plate 136, the middle rear side frame plate 131, and the middle rear bottom frame plate 132 together form an accommodating space 135. The backlight module 15 is accommodated in the accommodating space 135 and is joined to the middle rear frame 13. The panel 16 and the backlight module 15 are joined to two opposite sides of the middle rear top frame plate 136. The rear plate 21 of the rear housing 2 is joined to the middle rear bottom frame plate 132. The top frame plate 22T, the first side frame plate 22S, and the second side frame plate 22S' of the rear housing 2 are joined to the middle rear side frame plate 131, and the front trim plate 23 of the rear housing 2 is joined to at least a part of the panel 16. Similarly, each of the foregoing connection manners may be independently different connection manners, and each of the connection manners may include integral forming or other physical connection manners such as adhering, clipping, mortising, or locking, all of which are covered in the scope of the embodiments of the present invention.

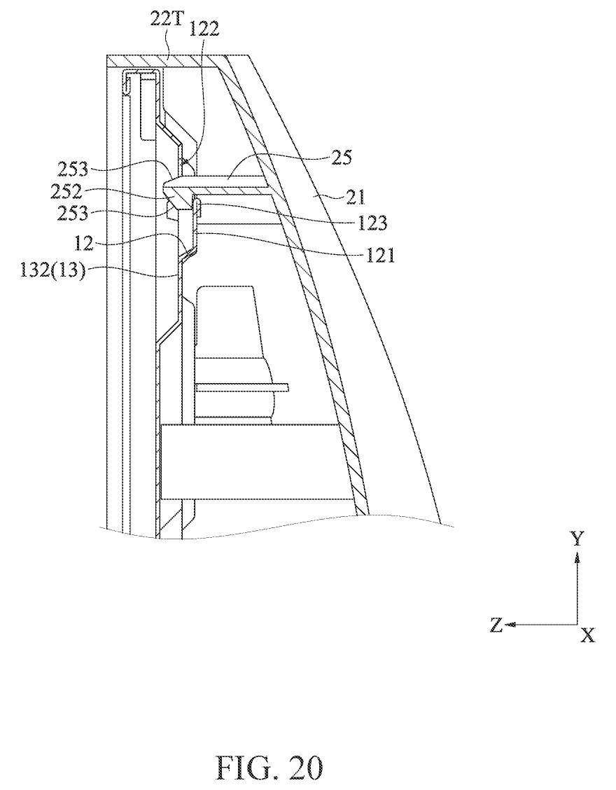

In some embodiments, the first fixing assembly portion 12 is arranged on the middle rear bottom frame plate 132 of the middle rear frame 13. To keep the drawings from being messy, in FIG. 20, merely the middle rear frame 13 in the panel assembly 1 is drawn as an example, but the present invention is not limited thereto. In other words, the first fixing assembly portion 12 may alternatively be arranged on another assembly in the panel assembly 1.

Referring to FIG. 20, in some embodiments, the plurality of first fixing portions 25 are located on the rear plate 21, so that the rear housing 2 and the panel assembly 1 are fixed to each other. One end of each of the first fixing portions 25 is located on the rear plate 21, and another end of the first fixing portion 25 is located on one of the first fixing assembly portion 12. Each of the first fixing portions 25 is arranged as a convex portion, and each of the first fixing assembly portions 12 is arranged as an opening and corresponds to each of the first fixing portions 25. The first fixing assembly portions 12 and the first fixing portions 25 correspond to each other and are matched with and hooked to each other. In this way, the first fixing portions 25 of the rear housing 2 are hooked to the first fixing assembly portions 12 of the panel assembly 1, and the first fixing portions 25 and the first fixing assembly portions 12 are matched with and hooked to each other, so that the panel assembly 1 and the rear housing 2 can be fixed to each other.

Still referring to FIG. 20, in some embodiments, the first fixing assembly portion 12 has a fixing assembly slot 121, the fixing assembly slot 121 has a second opening 122, and the second opening 122 is arranged at a bottom of the fixing assembly slot 121. The first fixing portion 25 is hooked to the second opening 122. In some embodiments, the fixing assembly slot 121 is located on a side of the panel assembly 1 facing the rear plate 21 and protrudes toward the first fixing portion 25. In this way, the first fixing portion 25 of the rear housing 2 is hooked to the second opening 122 of the panel assembly 1, and the first fixing portion 25 and the first fixing assembly portion 12 are matched with and hooked to each other, so that the panel assembly 1 and the rear housing 2 can be fixed to each other. In addition, through the arrangement of the fixing assembly slot 121 of the first fixing assembly portion 12, when the first fixing portion 25 is hooked to the first fixing assembly portion 12, the rear housing 2 can be quickly guided through the fixing assembly slot 121, and the rear housing 2 is assembled to the panel assembly 1, thereby reducing the assembly time of the elements.

Still referring to FIG. 20, in some embodiments, the first fixing portion 25 protrudes toward the panel assembly 1. A side of a free end of the first fixing portion 25 has a hook portion 252. In other words, a side located on another end of the first fixing portion 25 of the first fixing assembly portion 12 has the hook portion 252. The first fixing portion 25 is hooked to the first fixing assembly portion 12 through the hook portion 252. The first fixing portion 25 is hooked to the fixing assembly slot 121 through the hook portion 252.

Still referring to FIG. 20, in some embodiments, the fixing assembly slot 121 further has an inverted portion 123, and the inverted portion 123 is arranged on a side of the second opening 122. The inverted portion 123 is inverted (folded backward) toward the rear plate 21 of the rear housing 2. The hook portion 252 is hooked to the fixing assembly slot 121 and corresponds to the inverted portion 123. In this way, through the arrangement of the inverted portion 123, when the first fixing portion 25 is hooked to the first fixing assembly portion 12, a support force for the fixing assembly slot 121 can be provided, so that the hook portion 252 is effectively hooked to the fixing assembly slot 121.

Still referring to FIG. 20, in some embodiments, each of two sides of a terminal of the free end of the first fixing portion 25 has a third guide inclined surface 253. A height of each of the third guide inclined surfaces 253 increases in a direction from a position far away from the rear plate 21 to a position close to the rear plate 21. In other words, the height of each of the third guide inclined surfaces 253 increases in a direction in which the first fixing assembly portion 12 is connected to the first fixing portion 25. For example, in an embodiment, such direction is a direction in which the first fixing assembly portion 12 is embedded in the first fixing portion 25. In other words, a side of each of the third guide inclined surfaces 253 away from the rear plate 21 has a shortest height, and the closer each of the third guide inclined surfaces 253 is to the rear plate 21, the higher the height of each of the third guide inclined surfaces 253 is, so that a side of each of the third guide inclined surfaces 253 close to the rear plate 21 has a highest height. In this way, through the arrangement of the third guide inclined surfaces 253 of the first fixing portion 25, when the first fixing portion 25 is hooked to the first fixing assembly portion 12, the first fixing portion 25 can be quickly guided to the second opening 122, so that the hook portion 252 is effectively hooked to the fixing assembly slot 121, thereby reducing the assembly time of the elements.

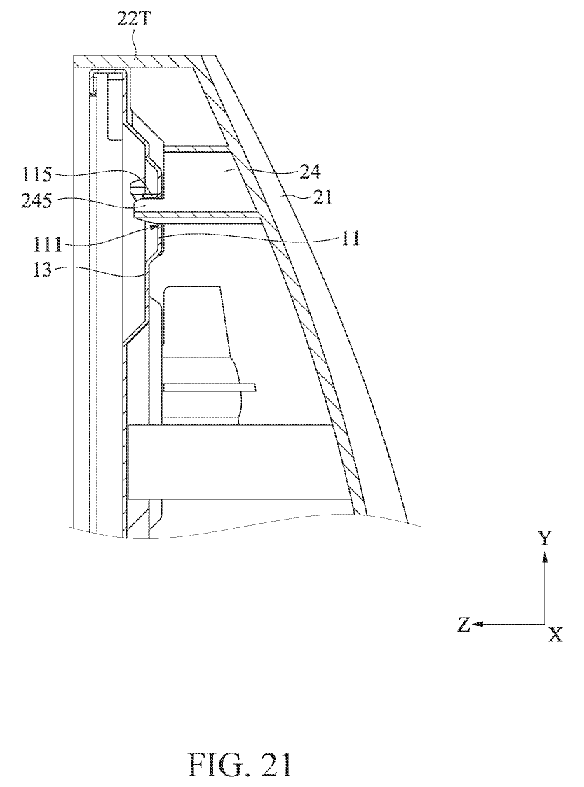

Referring to FIG. 21, structures of the limiting portion 24 and the limiting assembly portion 11 in a second embodiment are similar to structures in the first embodiment. Details are not described herein again.

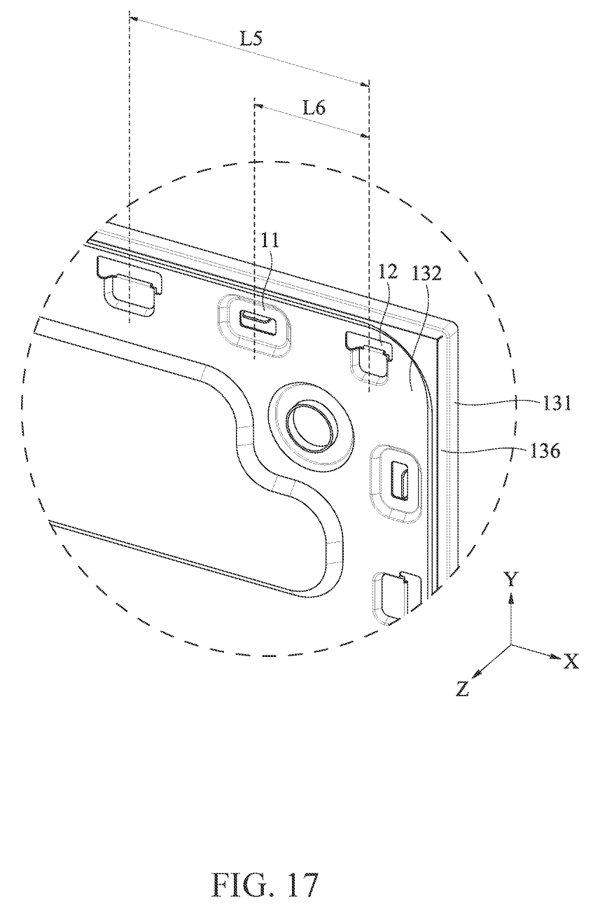

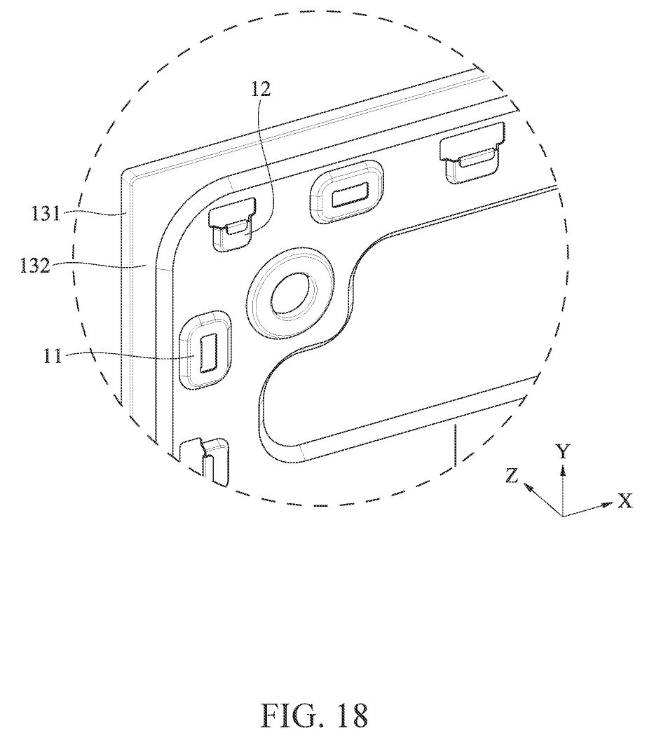

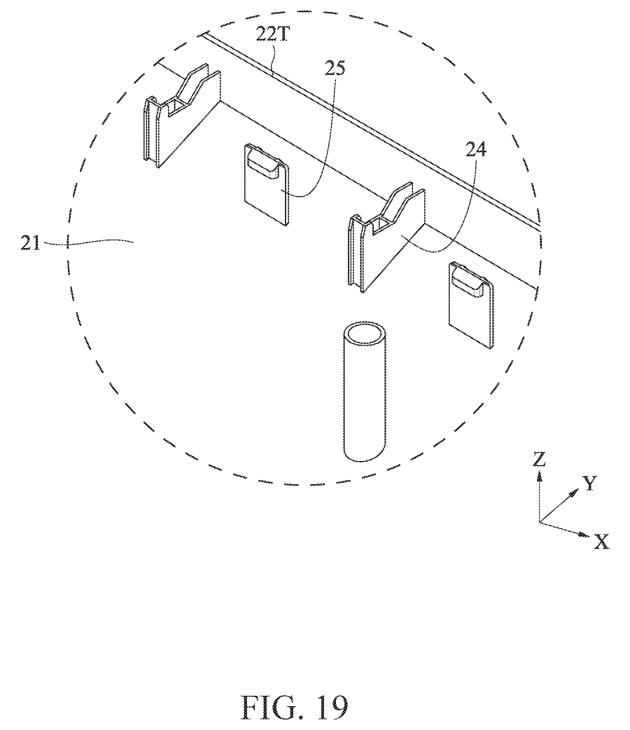

Referring to FIG. 17 and FIG. 18, the first fixing assembly portions 12 and the limiting assembly portions 11 are arranged in an alternating manner. The first fixing assembly portions 12 and the limiting assembly portions 11 are located on a side of the middle rear bottom frame plate 132 close to the middle side frame plate 141. Arrangement directions of the first fixing assembly portions 12 and the limiting assembly portions 11 are the same as axial directions of adjacent part of the middle side frame plate 141. Referring to FIG. 19, in some embodiments, the first fixing portions 25 and the limiting portions 24 are arranged in an alternating manner. Arrangement positions of the first fixing portions 25 correspond to arrangement positions of the first fixing assembly portions 12, and arrangement positions of the limiting portions 24 correspond to arrangement positions of the limiting assembly portions 11. The first fixing portions 25 and the limiting portions 24 are located on a side of the rear plate 21 close to the rear housing middle frame 22. Arrangement directions of the first fixing portions 25 and arrangement directions of the limiting portions 24 are the same as axial directions of adjacent parts of the rear housing middle frame 22. At least a part of the limiting portions 24 are connected to the adjacent parts of the rear housing middle frame 22. In the embodiment of FIG. 17, a spacing between two adjacent ones of the first fixing assembly portions 12 is L5, and each of the limiting assembly portion 11 is located between the two adjacent ones of the first fixing assembly portions 12. A distance between the first fixing assembly portion 12 and one of the two adjacent ones of the limiting assembly portions 11 which is adjacent to the first fixing assembly portion 12 is L6. L5 is 50 mm to 85 mm, and L6 is 20 mm to 45 mm. Under the condition of the foregoing spacing design, combined with size design and material selection of the first fixing assembly portions 12 and the limiting assembly portions 11, assembly strength needed by a design can be obtained.

Referring to FIG. 20 and FIG. 21 together, the limiting sub-portion 245 of the limiting portion 24 is limited by the first opening 111 of the limiting assembly portion 11, and a side of two sides of the first opening 111 that is close to the rear housing middle frame 22 has the ear portion 115. A side of the limiting sub-portion 245 abutting against a side of the first opening 111 having the ear portion 115 abuts against the ear portion 115. In other words, the limiting portion 24 provides a force toward the rear housing middle frame 22 to abut against the limiting assembly portion 11. The hook portion 252 of the first fixing portion 25 is hooked to the second opening 122 of the first fixing assembly portion 12, and a side of two sides of the second opening 122 that is away from the rear housing middle frame 22 has the inverted portion 123. A side of the first fixing portion 25 abutting against a side of the second opening 122 having the inverted portion 123 abuts against the fixing assembly slot 121. In other words, the first fixing portion 25 provides a force away from the rear housing middle frame 22 to abut against the first fixing assembly portion 12. In this way, a direction of the force provided by the limiting portion 24 is opposite to a direction of the force provided by the first fixing portion 25. After the first fixing portion 25 and the first fixing assembly portion 12 are fixed to each other, and the limiting portion 24 and the limiting assembly portion 11 are matched with each other, the assembly between the rear housing 2 and the panel assembly 1 can be more stable, thereby improving structural stability of the display device 100.

In other words, a side of the first fixing portion 25 abutting against a side of the second opening 122 having the inverted portion 123 abuts against the fixing assembly slot 121 in a negative Y-axis direction. In this case, to separate the first fixing portion 25 from the fixing assembly slot 121, the first fixing portion 25 needs to be moved in a positive Y-axis direction so that the first fixing portion 25 is separated from the fixing assembly slot 121. A side of the limiting sub-portion 245 abutting against a side of the first opening 111 having the ear portion 115 abuts against the ear portion 115 in the positive Y-axis direction. The limiting sub-portion 245 abutting against the ear portion 115 in the positive Y-axis direction may enable the rear housing 2 to be maintained in a state of being stably fitted to the panel assembly 1 when there is no external force to bend the first fixing portion 25 in the positive Y-axis direction and thus separated from the fixing assembly slot 121.

According to some embodiments, a housing of a display device includes an assembly middle frame 14, a middle rear frame 13, and a rear housing 2. The assembly middle frame 14 is fixed to the middle rear frame 13. The assembly middle frame 14 includes a plurality of first fixing assembly portions 12. The middle rear frame 13 includes a plurality of limiting assembly portions 11. The rear housing 2 includes a rear plate 21, a rear housing middle frame 22, a front trim plate 23, a plurality of limiting portions 24, and a plurality of first fixing portions 25. The rear housing middle frame 22 extends from the rear plate 21. For example, in an embodiment, the rear housing middle frame 22 extends from an edge of the rear plate 21 and includes a top frame plate 22T, a first side frame plate 22S, a second side frame plate 22S', and a bottom frame plate 22B. The front trim plate 23 extends from the bottom frame plate 22B, the limiting portions 24 are located on the rear plate 21, the limiting portions 24 are respectively connected to the limiting assembly portions 11, and the first fixing portions 25 are respectively connected to the first fixing assembly portions 12, so that the assembly middle frame 14 and the middle rear frame 13 are located between the rear plate 21 and the front trim plate 23.

In the foregoing descriptions, in some embodiments, the rear housing 2 is a one-piece structure, the limiting portions 24 are respectively matched with the limiting assembly portions 11, the first fixing portions 25 are respectively fixed to the first fixing assembly portions 12, first fixing portions 25 are located on the top frame plate 22T, the first side frame plate 22S, and the second side frame plate 22S', to enable the rear housing 2, the assembly middle frame 14, and the middle rear frame 13 to be fixed to each other respectively; a ratio of a thickness of an entirety obtained after the assembly middle frame 14 and the middle rear frame 13 are fixed to each other to a height of the front trim plate 23 is 35% to 70%; and each of the first fixing portions 25 has a first guide inclined surface 251, and a height of the first guide inclined surface 251 increases in a direction in which the first fixing assembly portion 12 is connected to the first fixing portion 25. For example, in an embodiment, such direction is a direction in which the first fixing assembly portion 12 is embedded in the first fixing portion 25.

According to some embodiments, the first fixing portions 25 are located on the rear plate 21to enable the rear housing 2 and the assembly middle frame 14 to be fixed to each other, and the first fixing assembly portions 12 and the limiting assembly portions 11 are arranged in an alternating manner.

According to some embodiments, each of the limiting assembly portions 11 has a first opening 111, and each of the limiting portions 24 is limited by each of the first opening 111. Each of the limiting portion 24 has a limiting slot 241, the limiting slot 241 is located on a side of the limiting portion 24 facing a corresponding one of the limiting assembly portions 11, two sides of the limiting slot 241 respectively have a support sub-portion 243 and a limiting sub-portion 245 that protrude toward a corresponding one of the limiting assembly portions 11, a distance between the support sub-portion 243 and the rear housing middle frame 22 is less than a distance between the limiting sub-portion 245 and the rear housing middle frame 22, the limiting sub-portion 245 is limited by a corresponding one of the first openings 111, and a width of each of the first opening 111 is greater than a width of the limiting sub-portion 245.

In conclusion, some embodiments of the present invention provide a display device 100 with a simple and convenient assembly process, which not only reduces assembly time and cost, but also reduces material costs. Similarly, the display device 100 also realizes a simple and convenient disassembly process.

What is claimed is:

1. A display device, comprising:
a panel assembly, comprising a panel, a plurality of limiting assembly portions, and a plurality of first fixing assembly portions; and
a rear housing, comprising a rear plate, a rear housing middle frame, a front trim plate, a plurality of limiting portions, and a plurality of first fixing portions, wherein the rear housing middle frame extends from the rear plate and comprises a top frame plate, a first side frame plate, a second side frame plate, and a bottom frame plate, the front trim plate extends from the bottom frame plate, the plurality of limiting portions are located on the rear plate, the plurality of limiting portions are respectively connected to the plurality of limiting assembly portions, the plurality of first fixing portions are respectively connected to the plurality of first fixing assembly portions, and the panel assembly to be located between the rear plate and the front trim plate.

2. The display device according to claim 1, wherein the rear housing is a one-piece structure, the plurality of limiting portions are respectively matched with the plurality of limiting assembly portions, the plurality of first fixing portions are respectively fixed to the plurality of first fixing assembly portions, the plurality of first fixing portions are located on the top frame plate, the first side frame plate, the second side frame plate, to fix the rear housing to the panel assembly; and each of the first fixing portions has a first guide inclined surface.

3. The display device according to claim 1, wherein each of the limiting assembly portions has a first opening, and a corresponding one of the limiting portions is limited by the first opening.

4. The display device according to claim 3, wherein each of the limiting portions has a limiting slot, the limiting slot is located on a side of each of the limiting portions facing a corresponding one of the limiting assembly portions, two sides of the limiting slot respectively have a support sub-portion and a limiting sub-portion that protrude toward the corresponding one of the limiting assembly portions, a distance between the support sub-portion and the rear housing middle frame is less than a distance between the limiting sub-portion and the rear housing middle frame, and the limiting sub-portion is limited by the first opening.

5. The display device according to claim 4, wherein a width of the first opening is greater than a width of the limiting sub-portion.

6. The display device according to claim 4, wherein a side of the first opening has an ear portion, and the ear portion protrudes away from the rear housing.

7. The display device according to claim 6, wherein a side of the limiting sub-portion has a first guide inclined side and an abutting side, one end of the first guide inclined side is connected to the abutting side, the abutting side pushes against the ear portion, another side of the limiting sub-portion has a second guide inclined side, and a spacing is provided between the second guide inclined side and the side of the first opening.

8. The display device according to claim 4, wherein a first gap is provided between the support sub-portion and the rear housing middle frame, and the panel assembly is partially arranged in the first gap.

9. The display device according to claim 1, wherein the plurality of first fixing portions are located on the rear plate, to fix the rear housing to the panel assembly.

10. The display device according to claim 9, wherein the first fixing assembly portions and the limiting assembly portions are arranged in an alternating manner.

11. The display device according to claim 9, wherein the first fixing portions protrude toward the panel assembly, a side of a free end of each of the plurality of first fixing portions has a hook portion, and each of the plurality of first fixing portions is hooked to a corresponding one of the plurality of first fixing assembly portions through the hook portion.

12. The display device according to claim 11, wherein each of the first fixing assembly portions has a fixing assembly slot, the fixing assembly slot has a second opening, the second opening is provided at a bottom of the fixing assembly slot, and a corresponding one of the first fixing portions is hooked to the fixing assembly slot through the hook portion.

13. The display device according to claim 12, wherein the fixing assembly slot further has an inverted portion, and the inverted portion is arranged on a side of the second opening and corresponds to the hook portion.

14. The display device according to claim 11, wherein each of two sides of a terminal of the free end of each of the first fixing portions has a third guide inclined surface.

15. The display device according to claim 1, wherein the rear housing further comprises a plurality of supporting portions supporting the panel assembly, a second gap is provided between the supporting portions and the rear housing middle frame, and the panel assembly is partially arranged in the second gap.

16. The display device according to claim 1, wherein the panel assembly further comprises an assembly middle frame and a middle rear frame, the assembly middle frame comprises a plurality of second fixing assembly portions, the middle rear frame comprises a plurality of second fixing portions, each of the second fixing portions is fixed to a corresponding one of the second fixing assembly portions, and each of the second fixing portion has a second guide inclined surface.

17. A housing of a display device, comprising:
an assembly middle frame, comprising a plurality of first fixing assembly portions;
a middle rear frame, comprising a plurality of limiting assembly portions, wherein the assembly middle frame is fixed to the middle rear frame; and
a rear housing, comprising a rear plate, a rear housing middle frame, a front trim plate, a plurality of limiting portions, and a plurality of first fixing portions, wherein the rear housing middle frame extends from the rear plate and comprises a top frame plate, a first side frame plate, a second side frame plate, and a bottom frame plate, the front trim plate extends from the bottom frame plate, the plurality of limiting portions are located on the rear plate, the plurality of limiting portions are respectively connected to the plurality of limiting assembly portions, the plurality of first fixing portions are respectively connected to the plurality of first fixing assembly portions, and the assembly middle frame and the middle rear frame to be located between the rear plate and the front trim plate.

18. The housing of the display device according to claim 17, wherein the rear housing is a one-piece structure, the plurality of limiting portions are respectively matched with the plurality of limiting assembly portions, the plurality of first fixing portions are respectively fixed to the plurality of first fixing assembly portions, the plurality of first fixing portions are located on the top frame plate, the first side frame plate, the second side frame plate, to fix the rear housing to the panel assembly; and each of the first fixing portions has a first guide inclined surface.

19. The housing of the display device according to claim 17, wherein the plurality of first fixing portions are located on the rear plate, to fix the rear housing to the panel assembly, and the first fixing assembly portions and the limiting assembly portions are arranged in an alternating manner.

20. The housing of the display device according to claim 17, wherein each of the limiting assembly portions has a first opening, and a corresponding one of the limiting portions is limited by the first opening; each of the limiting portions has a limiting slot, the limiting slot is located on a side of each of the limiting portions facing a corresponding one of the limiting assembly portions, two sides of the limiting slot respectively have a support sub-portion and a limiting sub-portion that protrude toward the corresponding one of the limiting assembly portions, a distance between the support sub-portion and the rear housing middle frame is less than a distance between the limiting sub-portion and the rear housing middle frame, and the limiting sub-portion is limited by the first opening; and a width of the first opening is greater than a width of the limiting sub-portion.
